(19) United States
(12) Patent Application Publication
(10) Pub. No.: US 2026/0009823 A1
(43) Pub. Date: Jan. 8, 2026

(54) PROBE CARD AND TEST SYSTEM INCLUDING THE SAME

(71) Applicant: Samsung Electronics Co., Ltd., Suwon-si (KR)

(72) Inventors: Seong Kwan LEE, Suwon-si (KR); Minho KANG, Suwon-si (KR); Jae Moo CHOI, Suwon-si (KR)

(73) Assignee: Samsung Electronics Co., Ltd., Suwon-si (KR)

(21) Appl. No.: 18/986,108

(22) Filed: Dec. 18, 2024

(30) Foreign Application Priority Data
Jul. 3, 2024 (KR) 10-2024-0087762

(51) Int. Cl. G01R 1/073; G01R 19/10

(52) U.S. Cl. CPC G01R 1/07342; G01R 19/10

(57) ABSTRACT

A test system includes a device power supply (DPS) supplying power to a device under test (DUT), which is a test target, and a probe card configured to contact the DUT and apply a test signal to the DUT, wherein the probe card includes a power transmission line electrically connected to the DPS and a first terminal of the DUT and configured to transmit power supplied from the DPS to the DUT, and a voltage sensing circuit electrically connected to the DPS and the first terminal and a second terminal of the DUT and configured to sense a voltage associated with the DUT and transmit the voltage to the DPS, and the voltage sensing circuit includes a subtractor configured to output a difference between a voltage of the first terminal and a voltage of the second terminal of the DUT.

### CROSS-REFERENCE TO RELATED APPLICATION

This application claims priority to Korean Patent Applications No. 10-2024-0087762, filed in the Korean Intellectual Property Office on Jul. 3, 2024, the entire contents of which are hereby incorporated by reference.

### BACKGROUND

### Technical Field

The present disclosure relates to probe cards and test systems including the same.

### Description of Related Art

Testing may be performed on semiconductor devices to determine a defective product. A test system may apply a test signal to devices under test (DUTs) such as semiconductor devices and analyze output electrical signals to determine if there is a defective semiconductor device. The test system may supply power for testing to the DUT through a probe card.

Meanwhile, an image sensor is a semiconductor device that converts an optical signal into an electrical signal to generate a digital image. Image sensors are essentially used in various electronic devices such as cameras, smartphones, and/or medical equipment. Because image sensors need high precision and accuracy, stable power supply is very important. In a device (e.g., camera, smartphone, etc.) where an image sensor is mounted, the image sensor can be positioned to be relatively close to a power supply and thus can receive power stably.

However, in the case of the test system, a distance between the image sensor as a DUT and the power supply may be relatively farther than the distance in the device where the image sensor is mounted. For this reason, it may be difficult for the image sensor to stably receive power from the test system. The instability in power supply may affect the operation of the image sensor, resulting in incorrect test results, and even a product that is actually a good product may be incorrectly classified as a defective product in testing.

The information described above is intended to improve understanding of the background of the present disclosure, and may include information that does not constitute the related art.

### SUMMARY

In order to solve one or more problems (e.g., the problems described above and/or other problems not explicitly described herein), the present disclosure provides probe cards and/or test systems including the same.

Some example embodiments of the present disclosure are not limited to the above, and other example embodiments not mentioned in the present disclosure may be clearly understood by those skilled in the art from the description of the present disclosure.

According to an example embodiment of the disclosure, a test system may include a device power supply configured to supply power to a device under test, which is a test target, and a probe card configured to contact the device under test and apply a test signal to the device under test, wherein the probe card includes a power transmission line electrically connected to the device power supply and a first terminal of the device under test and configured to transmit power supplied from the device power supply to the device under test, and a voltage sensing circuit electrically connected to the device power supply and the first terminal and a second terminal of the device under test, configured to sense a voltage associated with the device under test and transmit the voltage to the device power supply, and including a subtractor configured to output a difference between a voltage of the first terminal and a voltage of the second terminal of the device under test.

According to an example embodiment of the disclosure, a probe card configured to electrically connect a device power supply and a device under test. which is a test target, may include a power transmission line electrically connected to the device power supply and a first terminal of the device under test, the power transmission line configured to transmit power supplied from the device power supply to the device under test, and a voltage sensing circuit electrically connected to the device power supply and the first terminal and a second terminal of the device under test, the voltage sensing circuit configured to sense a voltage associated with the device under test and transmit the voltage to the device power supply, the voltage sensing circuit including a subtractor configured to output a difference between a voltage of the first terminal and a voltage of the second terminal of the device under test.

According to an example embodiment of the disclosure, a test system may include a device power supply configured to supply power to a device under test, which is a test target, and a probe card configured to electrically connect the device power supply and the device under test, the probe card configured to contact with the device under test and apply a test signal to the device under test, wherein the probe card may include a power transmission line electrically connected to the device power supply and a first terminal of the device under test, the power transmission line configured to transmit power supplied from the device power supply to the device under test, and a voltage sensing circuit including a subtractor configured to output a difference between a voltage of the first terminal and a voltage of a second terminal of the device under test, the voltage sensing circuit configured to transmit the difference between the voltage of the first terminal and the voltage of the second terminal outputted from the subtractor to the device power supply, and the device power supply may be configured to adjust power to be provided to the device under test based on the difference between the voltage of the first terminal and the voltage of the second terminal.

According to various example embodiments of the present disclosure, the difference between the operating voltage and the ground voltage, which is the voltage actually applied to the DUT, can be sensed. Based on this, the voltage applied to the DUT can be adjusted, so that the voltage actually applied to the DUT can be stably maintained. That is, the DUT can be stably supplied with power, and through this, the test on the DUT can be performed accurately.

According to various example embodiments of the present disclosure, it is possible to reduce or prevent a normal product from being incorrectly determined as a defective product during the test, and accordingly, it is possible to reduce or prevent a decrease in production yield.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail some example embodiments thereof with reference to the accompanying drawings, in which:

FIG. 1 is a block diagram provided to explain a test system;

FIG. 2 is a configuration diagram provided to explain a test system, and FIG. 3 is an enlarged view illustrating a portion A1 of FIG. 2 in more detail;

FIGS. 4 and 5 are circuit diagrams provided to explain a test system including a probe card;

FIG. 6 is a configuration diagram provided to explain a test system including a probe card, FIG. 7 is an enlarged view illustrating a portion A2 of FIG. 6, and FIG. 8 is an enlarged view illustrating a portion A3 of FIG. 6;

FIG. 9 is a block diagram provided to explain a test system including a utility board;

FIGS. 10 to 13 are circuit diagrams provided to explain a test system including a probe card including a switch;

FIG. 14 is a diagram illustrating an example of a voltage of a device under test (DUT) during testing of the DUT using a test system; and

FIG. 15 is a diagram illustrating an example of a test system.

### DETAILED DESCRIPTION

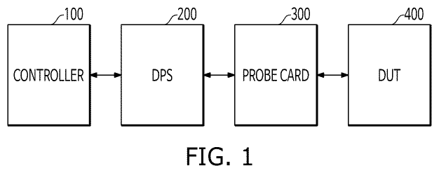

Hereinafter, various examples of the present disclosure will be described with reference to FIGS. 1 to 15. The same reference numerals may refer to the same components throughout the description.

FIG. 1 is a block diagram provided to explain a test system. Referring to FIG. 1, the test system may include a controller 100, a device power supply (DPS) 200, a probe card 300, and a device under test (DUT) 400. According to some examples, the controller 100 and/or the DUT 400 may be external components that are not included in the test system. Of course, the test system may further include additional test devices (e.g., a controller of the DUT, an image capture board, etc.) in addition to the illustrated components.

The DUT 400 may refer to a device to be tested. The test system may measure electrical characteristics of the DUT 400 to determine pass/fail of the DUT 400. For example, the test system may apply a test signal (e.g., a signal, power, etc.) to the DUT 400 and analyze a signal outputted from the DUT 400 in response to the applied test signal to determine the pass/fail of the DUT 400. The test system may apply a desired (or alternatively, predetermined) voltage level for each test mode to the DUT 400.

The DUT 400 may include an image sensor (e.g., a CMOS image sensor, etc.). The image sensor may be a semiconductor device used to convert an optical signal into an electrical signal to generate an image. For example, the DUT 400 may include at least one image sensor disposed on a wafer and/or include an image sensor manufactured in the form of a package, but is not limited thereto. The test system may apply various test signals including an optical signal to the DUT 400 including the image sensor and analyze an electrical signal outputted from the DUT 400 in response to the applied test signal to determine the pass/fail of the DUT 400.

The controller 100 may generally control most of the test devices in the test system. For example, the controller 100 may control the DPS 200 to provide a desired (or alternatively, predetermined) voltage level for each test mode to the DUT 400. The controller 100 may include a memory and a processor. Instructions for performing a test on the DUT 400 may be stored in the memory. The processor may control test devices (e.g., the DPS 200, etc.) in the test system by executing instructions stored in the memory, and accordingly, a test on the DUT 400 may be performed.

The DPS 200 may supply power to the DUT 400. For example, the DPS 200 may supply power to the DUT 400 through the probe card 300. The DPS 200 may include a regulator to stably supply power, but is not limited thereto. The DPS 200 may sense a voltage associated with the DUT 400 through the probe card and adjust a level of a voltage to be supplied to the DUT 400 based on the sensed voltage. By doing so, the DPS 200 may stably supply power to the DUT 400.

The probe card 300 may be an intermediate medium connecting the DUT 400 and the test device (e.g., the DPS 200 and/or a separate test device included in the test system). The probe card 300 may apply the test signal (e.g., power and/or an electrical signal, etc.) provided from the test device to the DUT 400. In addition, the probe card 300 may receive a signal output from the DUT 400 in response to the applied test signal and transmit the received signal to the test device. The probe card 300 may be brought into physical contact with the DUT 400 and directly connected to the DUT 400. An intermediate medium (e.g., an interface board (not shown)) may be further interposed between the probe card 300 and the test devices.

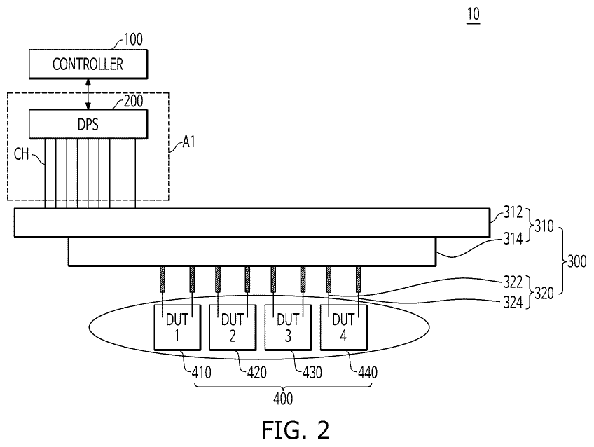

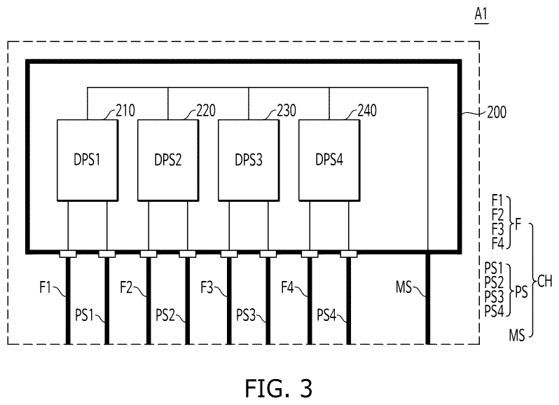

FIG. 2 is a configuration diagram provided to explain a test system 10, and FIG. 3 is an enlarged view illustrating a portion A1 of FIG. 2 in more detail. Referring to FIGS. 2 and 3, the test system 10 may include the controller 100, the DPS 200, the probe card 300, and the DUT 400. The controller 100 and/or the DUT 400 may be external components that are not included in the test system 10. The above description with reference to FIG. 1 may be applied equally/similarly below. Hereinafter, the elements or operations described above with reference to FIG. 1 will not be described again or briefly described, and those that have not been described in FIG. 1 will be mainly described.

The DUT 400 may refer to a device to be tested. The DUT 400 may include a plurality of DUTs 410, 420, 430 and 440. For example, a plurality of chips included in a wafer may be DUTs and the test system 10 may simultaneously test the plurality of DUTs 410, 420, 430 and 440. For example, the DUT 400 may include a plurality of image sensors included in a wafer, but is not limited thereto.

The probe card 300 may be an intermediate medium connecting the DUT 400 and the DPS 200. The probe card 300 may include a probe substrate 310 and a probe needle 320. The probe substrate 310 may include various circuits for transmitting an electrical signal between the DPS 200 and the DUT 400. For example, the probe substrate 310 may include wires to transmit electrical signals and circuit devices to perform simple pre/post-processing on electrical signals transmitted through the probe substrate 310.

The probe needle 320 may be formed on at least one end of the probe substrate 310. The probe needle 320 may be electrically connected to the probe substrate 310 (e.g., to the wires or circuit devices formed in the probe substrate 310). The probe needle 320 may be brought into physical contact with and electrically connected to a terminal of the DUT 400 (e.g., to a pad formed in the DUT 400) while the test on the DUT 400 is performed. For example, the probe needle 320 may include a first probe needle 322 and a second probe needle 324. The first probe needle 322 may be brought into contact with and electrically connected to a first terminal of the DUT 400, and the second probe needle 324 may be brought into contact with and electrically connected to a second terminal of the DUT 400. The first terminal of the DUT 400 may include an operating voltage VDD pad, and the second terminal may include a ground GND pad of the DUT 400. Furthermore, the second probe needle 324 in contact with the second terminal may be electrically connected to a ground of the probe card 300.

In an example in which the DUT 400 includes the plurality of DUTs 410, 420, 430 and 440, the probe needles 320 may be brought into physical contact with the terminals included in each of the DUTs 410, 420, 430 and 440 and electrically connected to each of the plurality of DUTs 410, 420, 430 and 440. For example, the probe needle 320 may include a plurality of first probe needles 322 and a plurality of second probe needles 324. The plurality of first probe needles 322 may be brought into contact with and electrically connected to the first terminals of the plurality of DUTs 410, 420, 430 and 440, and the plurality of second probe needles 324 may be brought into contact with and electrically connected to the second terminals of the plurality of DUTs 410, 420, 430 and 440.

The probe substrate 310 may include a main substrate 312 and a space transformer 314 interposed between the main substrate 312 and the probe needle 320. The space transformer 314 may electrically connect the probe needle 320 and the main substrate 312. For example, the main substrate 312 may include a printed circuit board (PCB), but is not limited thereto. Additionally, the space transformer 314 may include a multi-layer ceramic (MLC) structure in which wiring is placed within a multilayer ceramic substrate or a multi-layer organic (MLO) structure in which wiring is placed within a multilayer organic substrate, but is not limited thereto.

The probe card 300 (e.g., the probe substrate 310) may include a power transmission line and a voltage sensing circuit. The power transmission line may be electrically connected to the DPS 200 and the DUT 400 (e.g., the first terminal of the DUT 400), and may transmit power supplied from the DPS 200 to the DUT 400. The voltage sensing circuit may be electrically connected to the DPS 200 and the DUT 400 (e.g., the first and second terminals of the DUT 400), sense a voltage associated with the DUT 400, and transmit the sensed voltage to the DPS 200.

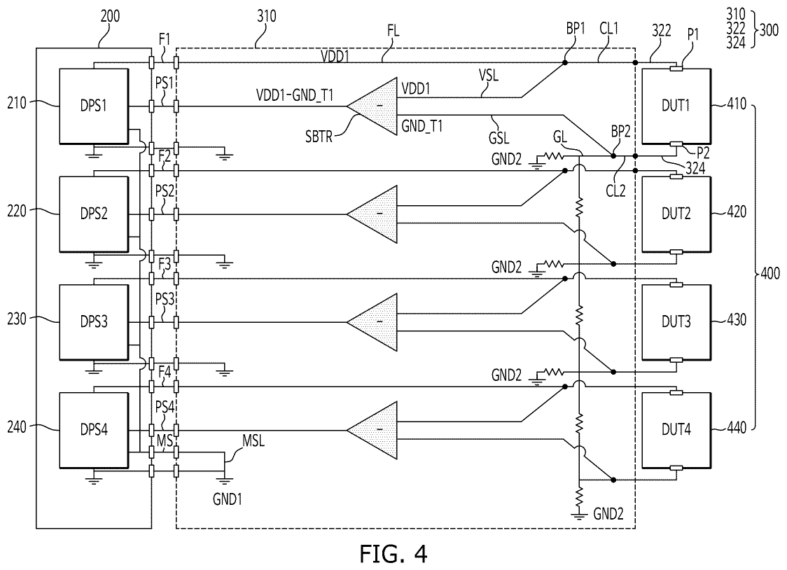

The voltage sensing circuit of the probe card 300 may sense a difference between the voltage of the first terminal and the voltage of the second terminal of the DUT 400 and transmit the sensed difference to the DPS 200. By doing so, the DPS 200 may sense the magnitude of the voltage actually applied to the DUT 400, and adjust a voltage level to be supplied to the DUT 400 based on the sensed magnitude of the voltage. That is, power may be stably supplied to the DUT 400. Accordingly, it is possible to reduce or prevent incorrect pass/fail judgment of the DUT 400 due to the instability of power supply. This will be described in more detail below with reference to FIGS. 4 to 14.

The DPS 200 may supply power to the DUT 400. For example, the DPS 200 may supply power to the DUT 400 through the power transmission line of the probe card 300. In addition, the DPS 200 may sense a voltage associated with the DUT 400 through the voltage sensing circuit of the probe card 300. The DPS 200 may supply power so that a desired (or alternatively, predetermined) voltage level for each test mode is applied to the DUT 400 under control of the controller 100.

The test system may further include a channel CH interposed between the DPS 200 and the probe card 300. The channel CH may be a signal line that electrically connects the DPS 200 and the probe card 300. The channel CH may include a forcing channel F, a plus sensing channel PS, and a minus sensing channel MS. The forcing channel F may be electrically connected to the DPS 200 and the power transmission line of the probe card 300. Power supplied from the DPS 200 may be transmitted to the power transmission line through the forcing channel F. The plus sensing channel PS may be electrically connected to the DPS 200 and the voltage sensing circuit of the probe card 300. A signal related to a voltage associated with the DUT 400, which is sensed by the voltage sensing circuit, may be transmitted to the DPS 200 through the plus sensing channel PS. Accordingly, the DPS 200 may sense the voltage associated with the DUT 400. The minus sensing channel MS may be electrically connected to the DPS 200 and the ground of the probe card 300. A signal related to a ground voltage (reference voltage) included in the probe card 300 may be transmitted to the DPS 200 through the minus sensing channel MS. Accordingly, the DPS 200 may sense the ground voltage of the probe card 300. The DPS 200 may adjust the voltage level to be provided to the DUT 400 based on the voltage sensed through the plus sensing channel PS and/or the minus sensing channel MS.

The DPS 200 may include a plurality of DPSs 210, 220, 230 and 240. Each of the plurality of DPSs 210, 220, 230 and 240 may supply power to a corresponding one of the DUTs 410, 420, 430 or 440. For example, the first DPS 210 may supply power to the first DUT 410 through a first forcing channel F1, and may sense a voltage associated with the first DUT 410 through a first plus sensing channel PS1. Similarly, the second DPS 220 may supply power to the second DUT 420 through a second forcing channel F2, and may sense a voltage associated with the second DUT 420 through a second plus sensing channel PS2. Each of the plurality of DPSs 210, 220, 230 and 240 may include a plurality of regulators for applying different voltage levels for each test mode to the DUT 400. In this way, each of separate DPSs 210, 220, 230 and 240 senses a voltage and supplies power to a corresponding one of the plurality of DUTs 410, 420, 430 or 440, and power may be stably supplied to the corresponding one of the plurality of DUTs 410, 420, 430 or 440.

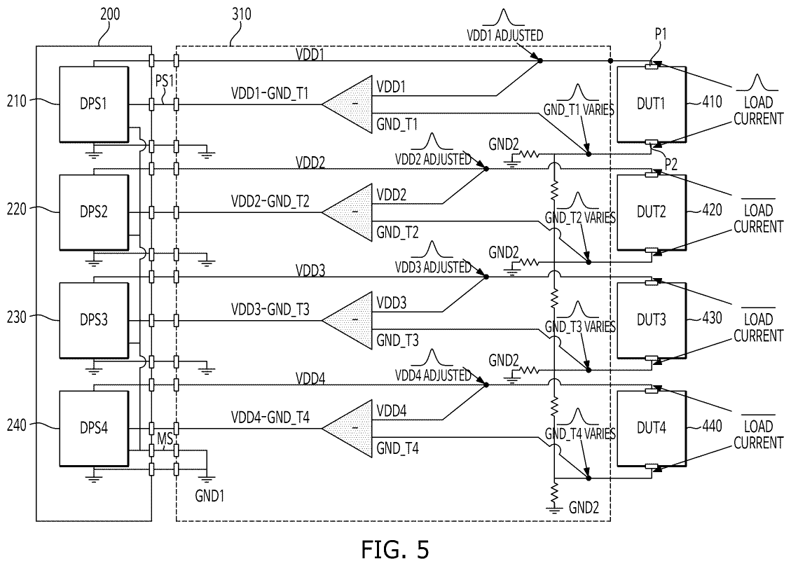

FIGS. 4 and 5 are circuit diagrams provided to explain a test system including the probe card 300. Referring to FIG. 4, the test system for testing the DUT 400 may include the DPS 200, the probe card 300, and channels F1, F2, F3, F4, PS1, PS2, PS3, PS4, and MS for electrically connecting the DPS 200 and the probe card 300.

The DPS 200 may supply power to the DUT 400 through the forcing channels F1, F2, F3, F4. In addition, the DPS 200 may sense a voltage associated with the DUT 400 through the plus sensing channels PS1, PS2, PS3, PS4. The minus sensing channel MS may be electrically connected to the first ground GND1 of the probe card 300 through a minus sensing line MSL of the probe card 300. The DPS 200 may sense a voltage of the first ground GND1 through the minus sensing channel MS. The first ground GND1 of the probe card 300 may be electrically connected to a ground of the DPS 200.

The DUT 400 may include a plurality of DUTs 410, 420, 430 and 440. Each of the plurality of DUTs 410, 420, 430 and 440 may include a first terminal P1 and a second terminal P2. The first terminal P1 may be an operating voltage VDD pad of the DUT 400, and the second terminal P2 may be a ground GND pad. The second terminal P2 of each of the plurality of DUTs 410, 420, 430 and 440 may be electrically connected to a second ground GND2 of the probe card 300 through a ground line GL. Although not described herein for the convenience of description, the second grounds GND2 of the probe card 300 connected to the second terminal P2 of each of the plurality of DUTs 410, 420, 430 and 440 may be electrically connected to one another. Also, although not shown, the first ground GND1 and the second ground GND2 of the probe card 300 may be electrically connected to each other. Ideally, a resistance of the ground line GL connecting the second terminal P2 of each of the plurality of DUTs 410, 420, 430 and 440 and the second ground GND2 of the probe card 300 and a resistance of the line connecting the first ground GND1 and the second ground GND2 of the probe card 300 may be zero. In some example embodiments, some resistance may be present in each line in an actual implementation.

The DPS 200 may include a plurality of DPSs 210, 220, 230 and 240. The plurality of DPSs 210, 220, 230 and 240 may supply power to the plurality of DUTs 410, 420, 430 and 440, respectively. Hereinafter, the test system will be described mainly with reference to the first DPS 210 of the plurality of DPSs 210, 220, 230 and 240, the first DUT 410 of the plurality of DUTs 410, 420, 430 and 440, and a circuit, of the circuits included in the probe card 300, associated with the first DPS 210 and the first DUT 410. The following descriptions on the first DUT 410 and the first DPS 210 may be applied equally/similarly to each of the plurality of DUTs 420, 430 and 440 and each of the plurality of DPSs 220, 230 and 240.

The probe card 300 may include the probe substrate 310, the first probe needle 322, and the second probe needle 324. The first probe needle 322 may be brought into contact with and electrically connected to the first terminal P1 of the first DUT 410, and the second probe needle 344 may be brought into contact with and electrically connected to the second terminal P2 of the first DUT 410.

The probe substrate 310 may include a power transmission line FL and a voltage sensing circuit. The power transmission line FL may be electrically connected to the first terminal P1 of the first DUT 410 through the first probe needle 322. In addition, the power transmission line FL may be electrically connected to the first DPS 210 through the first forcing channel F1. The DPS 200 may provide power (e.g., applying a desired (or alternatively, predetermined) level (e.g., 1.1V, 1.8V, 2.8V, etc.) of operating voltage VDD1) to the first terminal P1 of the first DUT 410. The power provided from the DPS 200 may be transmitted through the first forcing channel F1, the power transmission line FL, and the first probe needle 322, and the operating voltage VDD1 may be applied to the first terminal P1 of the DUT 400.

The voltage sensing circuit may be electrically connected to the first terminal P1 of the first DUT 410 through the first probe needle 322, and may be electrically connected to the second terminal P2 of the first DUT 410 through the second probe needle 324. In addition, the voltage sensing circuit may be electrically connected to the first DPS 210 through the first plus sensing channel PS1. The voltage sensing circuit may include a subtractor SBTR. The subtractor SBTR may include any circuit capable of outputting a difference between two input signals. The difference between two input signals may be a concept including a signal of amplified difference between two input signals. For example, the subtractor SBTR may include a differential amplifier, but is not limited thereto. In some example embodiments where the DUT 400 includes the plurality of DUTs 410, 420, 430,440, a separate subtractor SBRT may be provided for each device 410, 420, 430 and 440.

The voltage sensing circuit including the subtractor SBTR may sense a difference VDD1-GND_T1 between the voltage VDD1 of the first terminal of the first DUT 410 (e.g., the operating voltage of the first DUT 410) and the voltage GND_T1 of the second terminal (e.g., the ground voltage of the first DUT 410), and transmit the difference VDD1-GND_T1 to the first DPS 210. For example, a first input terminal of the subtractor SBTR may be electrically connected to the first terminal P1 of the first DUT 410 to receive the voltage VDD1 of the first terminal of the first DUT 410. In addition, a second input terminal of the subtractor SBTR may be electrically connected to the second terminal P2 of the first DUT 410 to receive the voltage GND_T1 of the second terminal of the first DUT 410.

For example, the first probe needle 322 in contact with the first terminal P1 of the first DUT 410 may be connected to a first connection line CL1 of the probe substrate 310. In addition, the first connection line CL1 of the probe substrate 310 may branch off from a first branch point BP1 to the power transmission line FL and the voltage sensing line VSL. The first input terminal of the subtractor SBTR may be connected to the voltage sensing line VSL to receive the voltage VDD1 of the first terminal. That is, the first input terminal of the subtractor SBTR may be electrically connected to the first terminal P1 through the first probe needle 322, the first connection line CL1, and the voltage sensing line VSL to receive the voltage VDD1 of the first terminal.

Furthermore, the second probe needle 324 in contact with the second terminal P2 of the first DUT 410 may be connected to a second connection line CL2 of the probe substrate 310. In addition, the second connection line CL2 of the probe substrate 310 may branch off from a second branch point BP2 to a ground line GL and a ground sensing line GSL. The second input terminal of the subtractor SBTR may be connected to the ground sensing line GSL to receive the voltage GND_T1 of the second terminal. That is, the second input terminal of the subtractor SBTR may be electrically connected to the second terminal P2 through the second probe needle 324, the second connection line CL2, and the ground sensing line GSL to receive the voltage GND_T1 of the second terminal.

In addition, an output terminal of the subtractor SBTR may be electrically connected to the first DPS 210. The difference VDD1-GND_T1 between the voltage of the first terminal and the voltage of the second terminal, which is outputted from the subtractor SBTR, may be provided to the first DPS 210 through the first plus sensing channel PS1.

The first DPS 210 may adjust power to be provided to the first DUT 410 based on the difference VDD1-GND_T1 between the voltage of the first terminal and the voltage of the second terminal sensed through the first plus sensing channel PS1. For example, the first DPS 210 may adjust the voltage VDD1 to be applied to the first terminal P1 so that the difference VDD1-GND_T1 between the voltage of the first terminal and the voltage of the second terminal, which is a voltage actually applied to the first DUT 410, is stably maintained.

Referring to FIG. 5, ideally, the resistance of the ground line GL connecting the second terminal P2 of each of the plurality of DUTs 410, 420, 430 and 440 and the second ground GND2 of the probe card 300, and the resistance of the line connecting the first ground GND1 and the second ground GND2 of the probe card 300 are 0, and thus the voltage of the first ground GND1 of the probe card 300, the voltage of the second ground GND2, and the voltage GND_T1, GND_T2, GND_T3 and GND_T4 of the second terminal of each of THE plurality of DUTs410, 420, 430 and 440 may all be the same. Note that, in an actual implementation, some resistance may be present in each line. Accordingly, as the current flows through at least some of the DUTs 410, 420, 430 and 440, not all of the voltage of the first ground GND1, the voltage of the second ground GND2, and the voltage GND_T1, GND_T2, GND_T3 and GND_T4 of the second terminal of each of the plurality of DUTs 410, 420, 430 and 440 may be the same. That is, in an actual implementation, it may be difficult for the DPS 200 to sense the voltage GND_T1, GND_T2, GND_T3 and GND_T4 of the second terminal of each DUT 400 only by sensing the voltage of the first ground GND1 through the minus sensing channel MS.

For example, as a load current is generated/varied between the first terminal P1 and the second terminal P2 of the first DUT 410 of the plurality of DUTs 410, 420, 430 and 440, the voltage GND_T1, GND_T2, GND_T3 and GND_T4 of the second terminal of each of the plurality of DUTs 410, 420, 430 and 440 may fluctuate unstably. According to a comparative example, this can cause the voltage between the first terminal P1 and the second terminal P2 of each of the DUTs 410, 420, 430 and 440 to fluctuate unstably, and it may affect the electrical signals outputted from the DUT 410, 420, 430 and 440. Thus, any of the DUT 410, 420, 430 and 440 that is actually a good product may be incorrectly determined as being defective.

The DPS 200 may sense, through the plus sensing channel PS, a difference (VDD1-GND_T1, VDD2-GND_T2, VDD3-GND_T3 and VDD4-GND_T4) between the voltage of the first terminal and the voltage of the second terminal, which is a voltage actually applied to the DUT 410, 420, 430 and 440, and adjust the voltage VDD1, VDD2, VDD3 and VDD4 to be applied to the first terminal P1 of the DUT 400 based on the sensed difference, thereby providing power so that the difference (VDD1-GND_T1, VDD2-GND_T2, VDD3-GND_T3 and VDD4-GND_T4) between the voltage of the first terminal and the voltage of the second terminal, which is the voltage actually applied to the DUT 410, 420, 430 and 440, can be stably maintained.

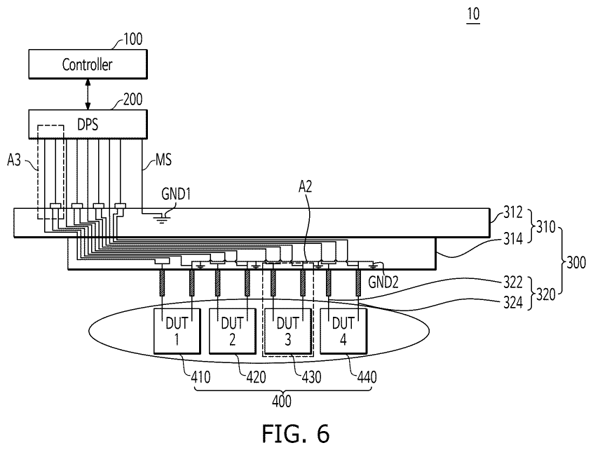

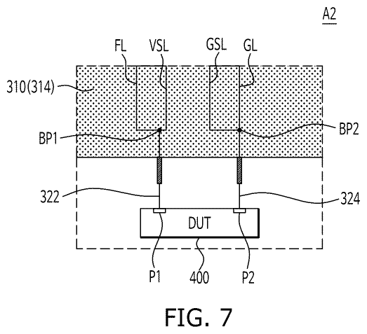

FIG. 6 is a configuration diagram provided to explain the test system including the probe card, FIG. 7 is an enlarged view illustrating a portion A2 of FIG. 6, and FIG. 8 is an enlarged view illustrating a portion A3 of FIG. 6.

Referring to FIG. 6, the test system 10 may include the controller 100, the DPS 200, the probe card 300, and the DUT 400. The controller 100 and/or the DUT 400 may be external components that are not included in the test system 10. The above descriptions with reference to FIGS. 1 to 5 may be applied equally/similarly below. Hereinafter, the elements or operations already described above will not be described again or briefly described, and those that have not been described above will be mainly described.

The probe card 300 may include the probe substrate 310 and the probe needle 320. The first probe needle 322 may be brought into contact with and electrically connected to the first terminal of the DUT 400, and the second probe needle 324 may be brought into contact with and electrically connected to the second terminal of the DUT 400. The probe substrate 310 may include the main substrate 312 and the space transformer 314 interposed between the main substrate 312 and the probe needle 320. The space transformer 314 may electrically connect the probe needle 320 and the main substrate 312.

The DPS 200 may be electrically connected to the first ground GND1 of the probe substrate 310 through the minus sensing channel MS. The DPS 200 may sense a voltage of the first ground GND1 through the minus sensing channel MS. The first ground GND1 of the probe substrate 310 electrically connected to the DPS 200 through the minus sensing channel MS may be positioned in the main substrate 312.

The DUT 400 may include a plurality of DUTs 410, 420, 430 and 440. The DUT 400 may be electrically connected to the second ground GND2 of the probe substrate 310 through the second probe needle 324. For example, the second ground GND2 of the probe substrate 310 may include a plurality of ground points electrically connected to one another, and the second probe needle 324 may include a plurality of second probe needles 324 in contact with the DUTs 410, 420, 430 and 440. Each of the plurality of DUTs 410, 420, 430 and 440 may be connected to a corresponding one of the plurality of ground points through a corresponding one of the plurality of second probe needles 324. The second ground GND2 of the probe substrate 310 electrically connected to the DUT 400 through the second probe needle 324 may be positioned in the space transformer 314. Although not shown, the first ground GND1 and the second ground GND2 may be electrically connected to each other within the probe substrate 310.

Referring to FIGS. 6 and 7, the first probe needle 322 may be brought into contact with and connected to the first terminal P1 of the DUT 400. Furthermore, the first probe needle 322 may be connected to the first connection line CL1 of the probe substrate 310. The first connection line CL1 may branch off from the first branch point BP1 in the probe substrate 310 to the power transmission line FL and the voltage sensing line VSL. That is, the power transmission line FL and the voltage sensing line VSL may be electrically connected to the first terminal P1 through the first connection line CL1 and the first probe needle 322. The first branch point BP1 may be positioned close to the first probe needle 322 (e.g., positioned closer to the first probe needle 322 than to the DPS 200) so that the voltage sensing line VSL can accurately sense the voltage of the first terminal P1. For example, the first branch point BP1 may be positioned in the space transformer 314.

The second probe needle 324 may be brought into contact with and connected to the second terminal P2 of the DUT 400. The second probe needle 324 may be connected to the second connection line CL2 of the probe substrate 310. The second connection line CL2 may branch off from the second branch point BP2 in the probe substrate 310 to the ground line GL and the ground sensing line GSL. That is, the ground line GL and the ground sensing line GSL may be electrically connected to the second terminal P2 through the second connection line CL2 and the second probe needle 324. The second branch point BP2 may be positioned close to the second probe needle 324 (e.g., positioned closer to the second probe needle 322 than to the DPS 200) so that the ground sensing line GSL can accurately sense the voltage of the second terminal P2. For example, the second branch point BP2 may be positioned in the space transformer 314.

Referring to FIGS. 6 and 8, the power transmission line FL of the probe substrate 310 may be electrically connected to the DPS 200 through the forcing channel F. The probe substrate 310 may include the subtractor SBTR. For example, the subtractor SBTR may be disposed on the main substrate 312. The input terminal of the subtractor SBTR may be electrically connected to the voltage sensing line VSL and the ground sensing line GSL, and the output terminal of the subtractor may be electrically connected to the DPS 200 through the plus sensing channel PS.

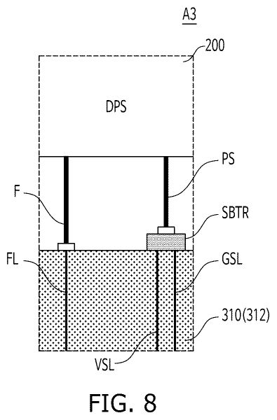

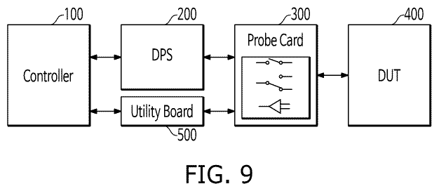

FIG. 9 is a block diagram provided to explain a test system including a utility board 500. Referring to FIG. 9, the test system may include the controller 100, the DPS 200, the probe card 300, the DUT 400, and the utility board 500. The controller 100 and/or the DUT 400 may be external components that are not included in the test system 10. The above descriptions with reference to FIGS. 1 to 8 may be applied equally/similarly below. Hereinafter, the elements or operations described above with reference to FIGS. 1 to 8 will not be described again or briefly described, and those that have not been described in FIGS. 1 to 8 or changes from those described above will be mainly described.

The probe card 300 may be an intermediate medium connecting the DUT 400 and the DPS 200. The probe card 300 may include various circuits for transmitting electrical signals between the DPS 200 and the DUT 400. For example, the probe card 300 may include wires to transmit electrical signals, circuit devices (e.g., a subtractor, etc.) to perform simple pre/post-processing on the electrical signals, and one or more switches to change the connection relationship of the circuits.

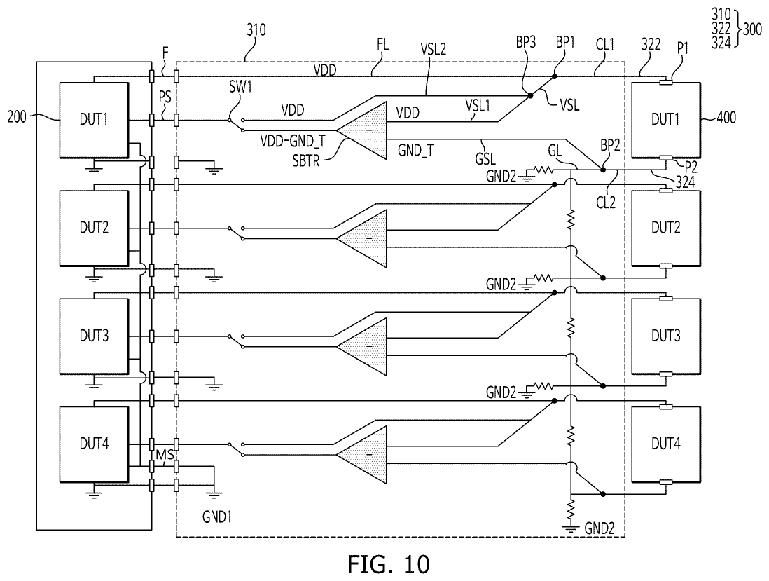

According to a switching state of the switch included in the probe card 300, the voltage of the first terminal of the DUT 400 or the difference between the voltage of the first terminal of the DUT 400 and the voltage of the second terminal may be selectively transmitted to the DPS 200. This will be described in more detail below with reference to FIGS. 10 to 13.

The utility board 500 may supply power to various circuit devices (e.g., subtractor, etc.) included in the probe card 300. In addition, the utility board 500 may change the connection relationship of the circuits in the probe card 300 by controlling the switch included in the probe card 300. For example, the utility board 500 may control the switch to change a connection relationship for each test mode. The utility board 500 may control the switch included in the probe card 300 based on a control signal received from the controller 100.

FIGS. 10 to 13 are circuit diagrams provided to explain a test system including a probe card including a switch.

Referring to FIGS. 10 to 13, the test system for testing the DUT 400 may include the DPS 200, the probe card 300, and the channels F, PS, and M for electrically connecting the DPS 200 and the probe card 300. The DUT 400 may include a plurality of DUTs, and the DPS 200 may include a plurality of DPSs 200 that supply power to the plurality of DUTs, respectively. Hereinafter, for the convenience of explanation, one DPS and one DUT will be described, but the following contents may be applied equally/similarly to an example in which the plurality of DPSs 200 and the plurality of DUTs 400 are included.

The probe card 300 may include a first switch SW1. A difference (VDD-GND_T) between the voltage of the first terminal of the DUT 400 and the voltage of the second terminal, or the voltage VDD of the first terminal may be selectively provided to the DPS 200 through the plus sensing channel PS according to a switching state of the first switch SW1. For example, the voltage sensing circuit of the probe substrate 310 may include the first switch SW1. The voltage sensing circuit may selectively transmit the difference (VDD-GND_T) between the voltage of the first terminal of the DUT 400 and the voltage of the second terminal, or the voltage VDD of the first terminal to the DPS 200 according to the switching state of the first switch SW1. The first switch SW1 may be included in another configuration interposed between the probe card 300 and the DPS 200.

For example, the first probe needle 322 in contact with the first terminal P1 of the DUT 400 may be connected to the first connection line CL1 of the probe substrate 310. In addition, the first connection line CL1 may branch off from the first branch point BP1 in the probe substrate 310 to the power transmission line FL and the voltage sensing line VSL. In addition, the voltage sensing line VSL may branch off from a third branch point BP3 in the probe substrate 310 to a first voltage sensing line VSL1 and a second voltage sensing line VSL2. That is, both the first voltage sensing line VSL1 and the second voltage sensing line VSL2 may be electrically connected to the first terminal P1 of the DUT 400 to sense the voltage VDD of the first terminal.

The second probe needle 324 in contact with the second terminal P2 of the DUT 400 may be connected to the second connection line CL2 of the probe substrate 310. In addition, the second connection line CL2 may branch off from the second branch point BP2 in the probe substrate 310 to the ground line GL and the ground sensing line GSL. That is, the ground sensing line GSL may be electrically connected to the second terminal P2 of the DUT 400 to sense a voltage GND_T of the second terminal.

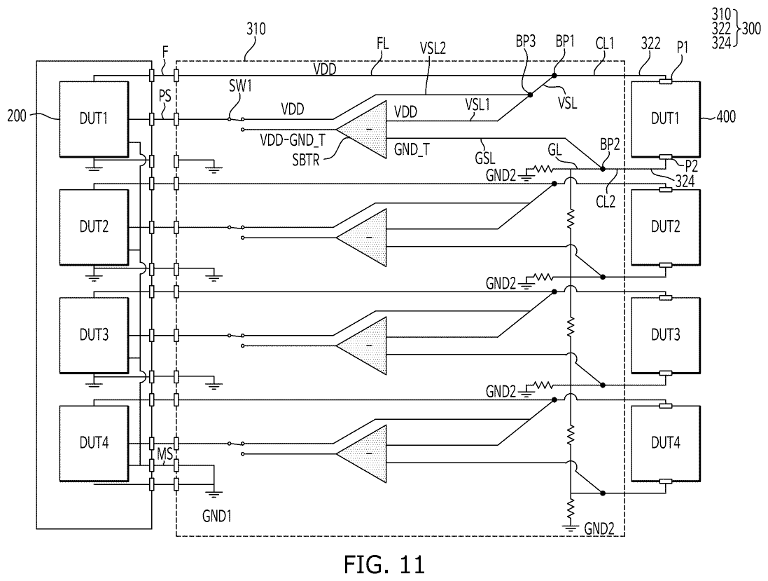

Referring to FIGS. 10 and 11, the first input terminal of the subtractor SBTR may be connected to the first voltage sensing line VSL1 to receive the voltage VDD of the first terminal. That is, the first input terminal of the subtractor SBTR may be electrically connected to the first terminal P1 through the first probe needle 322, the first connection line CL1, the voltage sensing line VSL, and the first voltage sensing line VSL1 to receive the voltage VDD of the first terminal.

The second input terminal of the subtractor SBTR may be connected to the ground sensing line GSL to receive the voltage GND_T of the second terminal. That is, the second input terminal of the subtractor SBTR may be electrically connected to the second terminal P2 through the second probe needle 324, the second connection line CL2, and the ground sensing line GSL to receive the voltage GND_T1 of the second terminal.

The output terminal of the subtractor SBTR may output a difference (VDD-GND_T) between the voltage of the first terminal and the voltage of the second terminal.

According to the switching state of the first switch SW1, the output terminal of the subtractor SBTR may be electrically connected to or disconnected from the DPS 200. For example, one end of the first switch SW1 may be connected to the DPS 200 through the plus sensing channel PS, and the other end of the first switch SW1 may be electrically connected to the output terminal of the subtractor SBTR or to the second voltage sensing line VSL2 according to the switching state of the first switch SW1.

For example, in a first mode, as illustrated in FIG. 10, one end of the first switch SW1 may be connected to the DPS 200 through the plus sensing channel PS, and the other end of the first switch SW1 may be connected to the output terminal of the subtractor SBTR. That is, in the first mode, the voltage sensing circuit may sense the difference (VDD-GND_T) between the voltage of the first terminal and the voltage of the second terminal of the DUT 400, and may transmit the difference to the DPS 200.

In a second mode, as illustrated in FIG. 11, one end of the first switch SW1 may be connected to the DPS 200 through the plus sensing channel PS, and the other end of the first switch SW1 may be connected to the second voltage sensing line VSL2. That is, in the second mode, the voltage sensing circuit may sense the voltage VDD of the first terminal of the DUT 400 and transmit the voltage VDD to the DPS 200. The second mode may be a mode (e.g., an open/short test mode) in which a negative voltage (e.g., −1 V) is applied to the first terminal P1 of the DUT 400, but is not limited thereto.

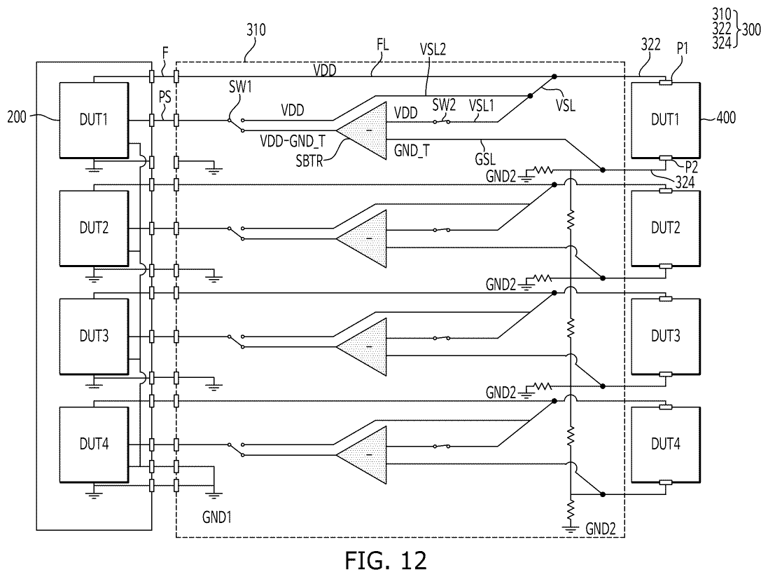

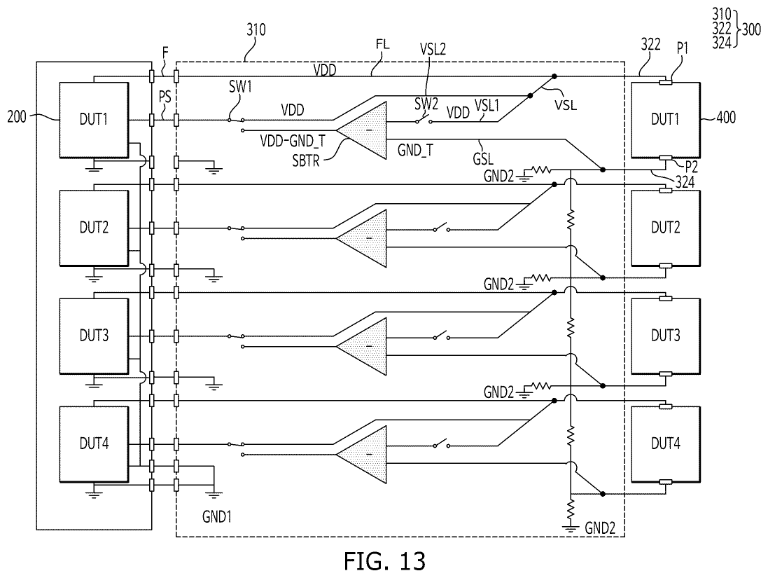

Referring to FIGS. 12 and 13, the probe card 300 (e.g., the voltage sensing circuit of the probe substrate 310) may further include a second switch SW2. According to the switching state of the second switch SW2, the first input terminal of the subtractor SBTR may be electrically connected to or disconnected from the first terminal P1 of the DUT 400. For example, the second switch SW2 may be interposed between the first input terminal of the subtractor SBTR and the first voltage sensing line VSL1. According to the switching state of the second switch, the first input terminal of the subtractor SBTR may be connected to or disconnected from the first voltage sensing line VSL1.

For example, in the first mode, as illustrated in FIG. 12, the second switch SW2 may connect the first input terminal of the subtractor SBTR and the first voltage sensing line VSL1. That is, in the first mode, the first input terminal of the subtractor SBTR may be electrically connected to the first terminal P1 of the DUT 400 through the first voltage sensing line VSL1 to receive the voltage VDD of the first terminal. In addition, in the first mode, the second input terminal of the subtractor SBTR may be connected to the ground sensing line GSL to receive the voltage GND_T of the second terminal. Accordingly, the output terminal of the subtractor SBTR may output the difference (VDD-GND_T) between the voltage of the first terminal and the voltage of the second terminal.

In addition, in the first mode, one end of the first switch SW1 may be connected to the DPS 200 through the plus sensing channel PS, and the other end of the first switch SW1 may be connected to the output terminal of the subtractor SBTR. That is, in the first mode, the voltage sensing circuit may sense the difference (VDD-GND_T) between the voltage of the first terminal and the voltage of the second terminal of the DUT 400, and may transmit the difference to the DPS 200.

In the second mode, as illustrated in FIG. 13, the second switch SW2 may be opened to disconnect the first input terminal of the subtractor SBTR and the first voltage sensing line VSL1. In addition, in the second mode, one end of the first switch SW1 may be connected to the DPS 200 through the plus sensing channel PS, and the other end of the first switch SW1 may be connected to the second voltage sensing line VSL2. That is, in the second mode, the voltage sensing circuit may sense the voltage VDD of the first terminal of the DUT 400 and transmit the voltage VDD to the DPS 200. The second mode may be a mode (e.g., an open/short test mode) in which a negative voltage (e.g., −1 V) is applied to the first terminal P1 of the DUT 400, but is not limited thereto.

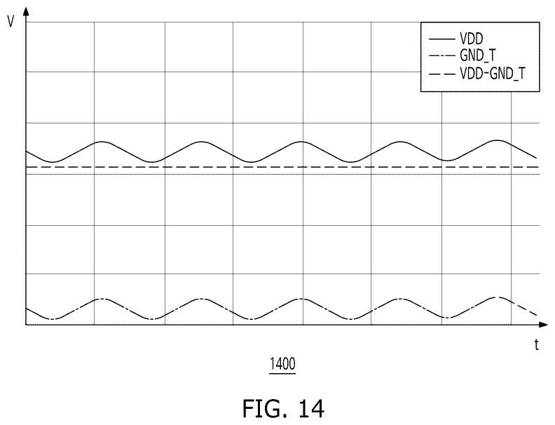

FIG. 14 is a diagram illustrating an example 1400 of a voltage of a DUT while the DUT is tested using the test system. Referring to FIG. 14, as a load current is generated/varied in the DUT during the test, a ground voltage (a voltage of a second terminal of the DUT, GND_T) of the DUT may fluctuate unstably. According to a comparative example, this causes the voltage applied to the DUT to fluctuate unstably, and it may affect the electrical signal outputted from the DUT. Thus, the DUT that is actually a good product may be incorrectly determined as defective.

The difference between the operating voltage and the ground voltage of the DUT (difference (VDD-GND_T) between the voltage of the first terminal and the voltage of the second terminal of the DUT) may be sensed. Based on this, as shown, the operating voltage VDD applied to the first terminal of the DUT is adjusted so that the difference (VDD-GND_T) between the operating voltage and the ground voltage, which is the voltage actually applied to the DUT, can be stably maintained. That is, the DUT can be stably supplied with power, and through this, the test on the DUT can be performed accurately.

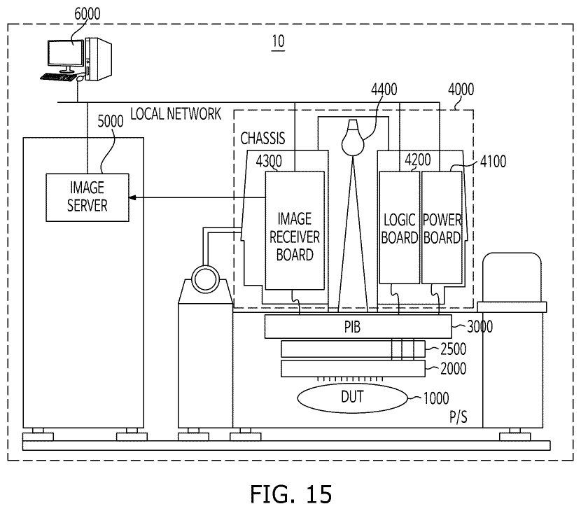

FIG. 15 is a diagram illustrating an example of the test system 10. Referring to FIG. 15, the test system 10 may include a DUT 1000 which is a test target, a probe card 2000, a test device 4000, and a server 5000.

The DUT 1000 may be a device that requires verification before product release. The DUT 1000 may include an image sensor (e.g., a CMOS image sensor). For example, the DUT 1000 may include at least one image sensor on a wafer or an image sensor manufactured in the form of a package.

The probe card 2000 may be provided to perform a test process of applying an electrical signal to the DUT 1000 and determining the pass/fail of image sensors based on a signal outputted from the DUT 1000 in response to the applied electrical signal. In addition, the probe card 2000 may be applied to any test process for testing the pass/fail of the DUT 1000.

For example, the probe card 2000 may apply an electrical signal (e.g., at least one of power or signal) provided from the test device 4000 to the DUT 1000, and transmit an output signal outputted in response to the applied electrical signal to the test device 4000. During the test process, the probe needle may be brought into physical contact with a terminal (for example, a pad) of the DUT 1000 to transmit an electrical signal to the DUT or receive a signal outputted from the DUT. Such probe needle may also be referred to as a probe pin or a probe. The probe card 2000 may be a cantilever probe card, a vertical probe card, a membrane probe card, a micro-electro-mechanical systems (MEMS) probe card, etc.

The test device 400 may simultaneously test a plurality of DUTs. For example, the DUT may include a plurality of DUTs included on one wafer, but is not limited thereto. The number of DUTs that the test device may simultaneously test may be limited by the number of channels, the number of probe needless included in the probe card, the number of terminals of the DUT, etc.

The test system may further include a pogo block 2500 and an interface board PIB 3000.

The pogo block 2500 may include a plurality of pins for connecting the probe card 2000 and the interface board 3000. Each of the plurality of pins may include a pogo pin.

The interface board 3000 may be implemented to map the probe card 2000 and the test device 4000 to each other. In addition, the interface board 3000 may include an active interface module for compensating for signal loss caused by the probe card 2000 and the pogo block 2500. The active interface module may be implemented according to communication standards of the DUT 1000. The active interface module may be modularly implemented to be inserted into the interface board 3000 through a module connector. For example, the active interface module may be implemented appropriately for any one of Mobile Industry Processor Interface (MIPI) C-PHY, MIPI D-PHY, MIPI M-PHY, or MIPI A-PHY. The MIPI may be a serial interface that connects hardware and software between a processor and peripheral devices. The active interface module may additionally convert the compensated signal into a signal advantageous for a long-distance signal. The active interface module may include a signal compensation circuit for compensating for losses between the wafer and the probe card 2000 and between the pogo block 2500 and the interface board 3000.

The active interface module may include a long-distance signal generation circuit that changes to a differential signal level advantageous for long distances without changing a frequency thereof. The active interface module may include a standard responding circuit that may respond even if the interface outputted from the wafer is changed. The active interface module may modularize the signal compensation circuit, the long-distance signal generation circuit, and the standard responding circuit described above. Meanwhile, the active interface module is not limited to the MIPI standards described above. The active interface module may perform communication according to any type of communication interface corresponding to a serial interface standard outputted from a CMOS image sensor.

In addition, the interface board 3000 may receive an image signal of the DUT 1000 transmitted from the probe card 2000 of the DUT 1000.

The test device 4000 may be implemented to transmit input and control signals to at least one image sensor through the probe card 2000. The test device 4000 may be implemented to simultaneously test the DUTs 1000. The DUT 1000 may include a wafer including a plurality of image sensors. The test device 4000 may be connected to the interface board 3000 through a cable.

The test device 4000 may be implemented to perform a signal analysis function, a DC test function, a reference voltage control function, etc. The signal analysis function may include receiving an image signal from the DUT 1000 and analyzing the received image signal. The signal analysis function may include correcting an error which occurs when a high-speed serial signal is distorted due to the influence of the transmission line or when a time delay occurs. The DC test function may include receiving a voltage associated with the DUT 1000 and comparing the received voltage with a test load voltage. The reference voltage control function may include controlling a reference voltage generation circuit of the interface board 3000 to reduce a deviation between components.

The test device 4000 may include a DPS 4100, a controller 4200 of the DUT, an image capture board (alternatively referred to as an image receiver board) ICB 4300, and a light source 4400. The DPS 4100 may supply power to the DUT 1000. The controller 4200 of the DUT may control the DUT 1000 to output an image. The image capture board 4300 may be implemented to analyze image signals received from the interface board 3000 and output the analyzed signals to the image server 5000.

The image capture board 4300 may be implemented to apply a voltage/current to the signal line (e.g., channel) or measure the voltage/current of the signal line to test electrical characteristics of the DUT. The image capture board 4300 may transmit a test current to a signal line corresponding to a signal line open test. The image capture board 4300 may generate an active resistance to reduce or eliminate a load resistance error when testing output voltage of the DUT 1000.

The light source 4400 may be implemented to irradiate light to the DUT 1000. The light source 4400 may irradiate light of various illuminance to the DUT 1000. That is, the test device 4000 may control the light source 4400 to input light of various illuminance to the DUT 1000. An output signal (e.g., an image signal) of the DUT 1000 corresponding to the input illumination light may be transmitted to the image capture board 43000 through the probe card 2000 (e.g., an output probe of the probe card 2000).

The image server 5000 may be implemented to perform image processing of a signal transmitted from the test device 4000. The data after image processing may be transmitted to an external device (e.g., controller 6000) through a network.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to some example embodiments, it is possible to reduce or prevent incorrect pass/fail judgment of a DUT (e.g., an image sensor) due to the instability of power supply. Depending on the judgement results, passed DUTs may sorted out as good products and proceed to other subsequent processes, and failed DUTs may be discarded, reworked or refurbished, or downgraded.

It should be understood that example embodiments described herein should be considered in a descriptive sense only and not for purposes of limitation. While some example embodiments have been particularly shown and described, it will be understood by one of ordinary skill in the art that variations in form and detail may be made therein without departing from the spirit and scope of the claims.

What is claimed is:

1. A test system, comprising:
a device power supply configured to supply power to a device under test, which is a test target; and
a probe card which configured to contact with the device under test and apply a test signal to the device under test, wherein
the probe card comprises
a power transmission line electrically connected to the device power supply and a first terminal of the device under test and configured to transmit power supplied from the device power supply to the device under test, and
a voltage sensing circuit electrically connected to the device power supply and the first terminal and a second terminal of the device under test, configured to sense a voltage associated with the device under test and transmit the voltage to the device power supply, and including a subtractor configured to output a difference between a voltage of the first terminal and a voltage of the second terminal of the device under test.

2. The test system of claim 1, wherein
the subtractor comprises
a first input terminal electrically connected to the first terminal,
a second input terminal electrically connected to the second terminal, and
an output terminal electrically connected to the device power supply, and
the voltage sensing circuit is configured to transmit the difference between the voltage of the first terminal and the voltage of the second terminal outputted from the subtractor to the device power supply.

3. The test system of claim 1, wherein
the first terminal comprises an operating voltage pad, and
the second terminal comprises a ground pad.

4. The test system of claim 1, wherein
the probe card comprises
a first probe needle configured to contact and electrically connect the first terminal, and
a probe substrate comprising a first connection line electrically connected to the first probe needle, the power transmission line, and the voltage sensing circuit, and
an input terminal of the subtractor and the power transmission line are electrically connected to the first terminal through the first probe needle.

5. The test system of claim 4, wherein
the first connection line branches off from a first branch point of the probe substrate into the power transmission line and a voltage sensing line, and
the input terminal of the subtractor is electrically connected to the first terminal through the first probe needle and the voltage sensing line.

6. The test system of claim 5, wherein
the probe substrate comprises
a main substrate, and
a space transformer connecting the main substrate and the probe needle, the space transformer comprising the first branch point from which the power transmission line and the voltage sensing line branch off.

7. The test system of claim 1, wherein
the probe card comprises,
a second probe needle configured to contact and electrically connect the second terminal; and
a probe substrate comprising a second connection line electrically connected to the second probe needle, a ground, a ground line electrically connecting the ground and the second terminal, and the subtractor, and
an input terminal of the subtractor is electrically connected to the second terminal through the second probe needle.

8. The test system of claim 7, wherein
the second connection line branches off from a second branch point of the probe substrate into the ground line and a ground sensing line, and
the subtractor is electrically connected to the second terminal through the second probe needle and the ground sensing line.

9. The test system of claim 8, wherein
the probe substrate comprises
a main substrate, and
a space transformer configured to connect the main substrate and the probe needle, the space transformer comprising the second branch point from which the ground line and the ground sensing line branch off.

10. The test system of claim 7, wherein
the ground of the probe card comprises a plurality of ground points electrically connected to one another, and
the ground points of the probe card are configured to be electrically connected to second terminals included in each of a plurality of devices under test, respectively, each of the plurality of devices under test comprising the device under test.

11. The test system of claim 1, wherein
the probe card further comprises a first switch, and
the voltage sensing circuit is configured to selectively transmit, according to a switching state of the first switch, the difference between the voltage of the first terminal and the voltage of the second terminal or the voltage of the first terminal to the device power supply.

12. The test system of claim 11, wherein the first switch is configured to connect or disconnect the subtractor and the device power supply according to the switching state thereof.

13. The test system of claim 11, wherein
the probe card further comprises a first voltage sensing line and a second voltage sensing line which are electrically connected to the first terminal,
an input terminal of the subtractor is electrically connected to the first terminal through the first voltage sensing line, and
one end of the first switch is connected to the device power supply, and the other end of the first switch is electrically connected to an output terminal of the subtractor or the second voltage sensing line.

14. The test system of claim 11, wherein
the probe card further comprises a second switch, and
the second switch is configured to electrically connect or disconnect the subtractor and the first terminal of the device under test according to a switching state thereof.

15. The test system of claim 1, further comprising:
a utility board configured to control a switch included in the probe card and supply power to a circuit device included in the probe card.

16. The test system of claim 1, wherein the device under test comprises an image sensor.

17. The test system of claim 1, wherein
the device under test comprises a first device under test and a second device under test, and
the device power supply comprises
a first device power supply configured to supply power to the first device under test, and
a second device power supply configured to supply power to the second device under test.

18. The test system of claim 1, further comprising:
a channel interposed between the device power supply and the probe card, the channel configured to electrically connect the device power supply and the probe card, wherein
the channel comprises
a forcing channel connected to the power transmission line of the probe card and configured to transmit power supplied from the device power supply,
a plus sensing channel electrically connected to the voltage sensing circuit of the probe card and configured to sense a voltage associated with the device under test, and
a minus sensing channel configured to sense a voltage of a ground included in the probe card.

19. A probe card configured to electrically connect a device power supply and a device under test, which is a test target, the probe card comprising:
a power transmission line electrically connected to the device power supply and a first terminal of the device under test, the power transmission line configured to transmit power supplied from the device power supply to the device under test; and
a voltage sensing circuit electrically connected to the device power supply and the first terminal and a second terminal of the device under test, the voltage sensing circuit configured to sense a voltage associated with the device under test and transmit the voltage to the device power supply, the voltage sensing circuit comprising a subtractor configured to output a difference between a voltage of the first terminal and a voltage of the second terminal of the device under test.

20. A test system, comprising:
a device power supply configured to supply power to a device under test, which is a test target; and
a probe card configured to electrically connect the device power supply and the device under test, the probe card configured to contact with the device under test and apply a test signal to the device under test, wherein
the probe card comprises
a power transmission line electrically connected to the device power supply and a first terminal of the device under test, the power transmission line configured to transmit power supplied from the device power supply to the device under test, and
a voltage sensing circuit comprising a subtractor configured to output a difference between a voltage of the first terminal and a voltage of a second terminal of the device under test, the voltage sensing circuit configured to transmit the difference between the voltage of the first terminal and the voltage of the second terminal outputted from the subtractor to the device power supply, and
the device power supply is configured to adjust power to be provided to the device under test based on the difference between the voltage of the first terminal and the voltage of the second terminal.
